(19) United States
(12) Patent Application Publication
(10) Pub. No.: US 2024/0213338 A1
(43) Pub. Date: Jun. 27, 2024

(54) FORMATION OF NON-SELF-ALIGNED BACKSIDE CONTACT

(71) Applicant: INTERNATIONAL BUSINESS MACHINES CORPORATION, ARMONK, NY (US)

(72) Inventors: Tao Li, Slingerlands, NY (US); Kisik Choi, Watervliet, NY (US); Nicolas Jean Loubet, Guilderland, NY (US); Julien Frougier, Albany, NY (US); Ruilong Xie, Niskayuna, NY (US)

(21) Appl. No.: 18/146,988

(22) Filed: Dec. 27, 2022

(51) Int. Cl. H01L 29/417; H01L 23/528; H01L 29/06; H01L 29/40; H01L 29/423; H01L 29/775

(52) U.S. Cl. CPC H01L 29/41766; H01L 23/5286; H01L 29/0673; H01L 29/401; H01L 29/41775; H01L 29/42392; H01L 29/775

(57) ABSTRACT

A semiconductor device includes a transistor device, including a source and drain region, and a gate region. A bottom dielectric isolation layer is on a backside of the transistor device. A buffer layer is on a backside of the bottom dielectric isolation layer. A first conductive contact is positioned on a backside of the transistor device in contact with a backside of the source and drain region, through the bottom dielectric isolation layer and through the buffer layer. A second conductive contact is in contact with the gate region from a frontside of the gate region.

### BACKGROUND

The present disclosure generally relates to electrical devices, and more particularly, to a formation of non-self-aligned backside contact.

In semiconductor device manufacture, conventional methods use frontside contact schemes during wafer processing. In frontside contact schemes, the overlay margins involved in forming frontside contacts are fairly accurate and easy to align with features on the frontside of the device.

The fabrication process is a multiple-step sequence of photolithographic and chemical processing steps (such as surface passivation, thermal oxidation, planar diffusion and junction isolation) during which electronic circuits are gradually created on a wafer made of pure semiconducting material. Silicon is almost always used, but various compound semiconductors are used for specialized applications. Some current fabrication techniques include forming features from both the frontside and the backside of a wafer. For example, processing features and other electronics can be powered by routing signals from a backside power delivery network.

### SUMMARY

According to an embodiment of the present disclosure, a semiconductor device is provided. The semiconductor device includes a transistor device, including a source and drain region, and a gate region. A bottom dielectric isolation layer is on a backside of the transistor device. A buffer layer is on a backside of the bottom dielectric isolation layer. A first conductive contact is positioned on a backside of the transistor device in contact with a backside of the source and drain region, through the bottom dielectric isolation layer and through the buffer layer. A second conductive contact is in contact with the gate region from a frontside of the gate region.

According to another embodiment of the present disclosure, a semiconductor device is provided. The semiconductor device includes a transistor device in a front end of line layer includes a source and drain region, and a gate region. A bottom dielectric isolation layer is in the front end of line layer and on a backside of the transistor device. A first sacrificial layer on a backside of the bottom dielectric isolation layer includes a first controlled opening. The semiconductor device also includes a middle of line layer. A back end of line layer is coupled to a frontside of the middle of line layer A first conductive contact positioned on a backside of the transistor device is in contact with a backside of the source and drain region, through the bottom dielectric isolation layer and through the first, controlled opening of the first sacrificial layer. A second conductive contact is in contact with the gate region from a frontside of the gate region and in contact with the back end of line layer. A backside power delivery network is coupled to a back side of the front end of line layer. A power rail in the backside power delivery network is in contact with a backside of the first conductive contact.

According to another embodiment of the present disclosure, a method of manufacturing a semiconductor device is provided. The method includes forming a transistor device including a source and drain region and a gate region. A bottom dielectric isolation layer is formed on a backside of the transistor device. A first opening in the bottom dielectric isolation layer is formed under a backside of the source and drain region. A sacrificial layer is formed on a backside of the bottom dielectric isolation layer. Material is selectively removed from the sacrificial layer. The formation of a second opening in the sacrificial layer is controlled from the selective removal of material. The second opening is positioned at least partly under the first opening. A conductive contact is formed from the backside of the sacrificial layer, in the first opening and in the second opening, in contact with the backside of the source and drain region, through the bottom dielectric isolation layer.

The techniques described herein may be implemented in a number of ways. Example implementations are provided below with reference to the following figures.

### BRIEF DESCRIPTION OF THE DRAWINGS

The drawings are of illustrative embodiments. They do not illustrate all embodiments. Other embodiments may be used in addition or instead. Details that may be apparent or unnecessary may be omitted to save space or for more effective illustration. Some embodiments may be practiced with additional components or steps and/or without all of the components or steps that are illustrated. When the same numeral appears in different drawings, it refers to the same or like components or steps.

FIGS. 1A-1C show cross-sectional views of a semiconductor device according to an embodiment of the present disclosure.

FIG. 2 is a legend showing axes from a top view perspective of an initial substrate formation, consistent with embodiments of the present disclosure.

FIGS. 3A-3C show cross-sectional views of a starting substrate formation for a semiconductor device, consistent with embodiments of the present disclosure.

FIGS. 4A-4C show views of patterning a stack of nanosheets on the substrate formation and forming shallow trench isolation areas, according to embodiments.

FIGS. 5A-5C show views of forming a dummy gate region, according to an embodiment.

FIGS. 6A-6C show views of a formation after being subjected to an etching process configuration out of the formation from FIGS. 5A-5C, according to an embodiment.

FIGS. 7A-7C show views of the formation of FIG. 6A-6C after the selective removal of a sacrificial layer, according to an embodiment.

FIGS. 8A-8C show views after forming a gate spacer and a bottom dielectric isolation layer, recessing a portion of the nanosheet stack, indenting layers of the nanosheet stack, and forming an inner spacer, according to an embodiment.

FIGS. 9A-9C show views after forming source and drain epitaxial growth regions, according to an embodiment.

FIGS. 10A-10C show views of replacing the dummy gate with a gate region, according to an embodiment.

FIG. 10D shows a view of the legend of FIG. 2 updated to show positioning of a gate cut formation in FIGS. 10A-10C.

FIGS. 11A-11C show views after depositing metal contacts in the middle of line region, according to an embodiment.

FIG. 11D shows a view of the legend of FIG. 10D updated to show a top view positioning of metal gates in FIGS. 11A-11C.

FIGS. 12A-12C show views after forming a back end of line layer and an attached carrier wafer, according to an embodiment.

FIGS. 13A-13C show views after removing a bottom substrate layer after a wafer flip, according to an embodiment.

FIGS. 14A-14C show views after removing the etch stop layer from the formation shown in FIGS. 13A-13C, according to an embodiment.

FIGS. 15A-15C show views of removing another substrate layer from the formation shown in FIGS. 14A-14C, according to an embodiment.

FIGS. 16A-16C show views after depositing a backside interlayer dielectric, according to an embodiment.

FIGS. 17A-17C show views after patterning out areas for backside metal contacts, according to an embodiment.

FIGS. 18A-18C show views after indenting a sacrificial layer adjacent patterned out areas for the backside contact, according to an embodiment.

FIGS. 19A-19C show views after forming an inner spacer in the areas indented in FIGS. 18A-18C, according to an embodiment.

FIGS. 20A-20C show views after indenting a second sacrificial layer adjacent the patterned-out areas for the backside contact, according to an embodiment.

FIGS. 21A-21C show views after forming an inner spacer in the areas indented in FIGS. 20A-20C, according to an embodiment.

FIGS. 22A-22C show views after removal of a buffer layer beneath one of the source and drain regions.

FIGS. 23A-23C show views after depositing contact metal into the backside contact areas, according to an embodiment.

FIGS. 24A-24C show views forming a backside power rail and backside power delivery network, according to an embodiment.

### DETAILED DESCRIPTION

### Overview

Some technologies related to semiconductor device manufacture increasingly use backside formed contacts. Forming contacts from the backside presents new challenges including, for example, where to position placeholder elements and how to remove some layers during the fabrication process to access elements above the target layers. In some applications, a backside contact provides an electrical connection to the source and drain of a transistor. The overlay margins for backside contacts can become more difficult to control when fabricating features from the backside of the wafer. Conventional techniques may fabricate a placeholder for the contact using a self-aligned contact technique. A source and drain may be grown over the placeholder. In this approach, the placeholder pre-defines the alignment with the source and drain for the eventual metal contact that is formed. The placeholder may be removed from the backside when the process is ready for metallization. The overlay margins near the connection to the source and drain can become harder to control when replacing the placeholder with the metal.

Embodiments of the semiconductor device technology disclosed herein address challenges related to protecting different device features while forming backside contacts during the fabrication process. Features of the subject semiconductor device and method of fabrication provide a backside contact by adding one or more buffer layers proximate the bottom dielectric isolation (BDI) layer adjacent the backside contact. The bottom dielectric isolation layer and transistor elements above the bottom dielectric isolation layer, (for example, the gate and source and drain) are protected by the buffer layers. In some aspects, the subject semiconductor device also avoids damage to the gate metal and to the bottom dielectric isolation layer that can sometimes occur during conventional contact formation from the frontside. In addition, the overlay misalignment for a backside contact is typically worse than the overlay for a frontside contact. If the overlay for a backside contact is bad enough, undesirable effects may occur including for example, short circuits between the backside contact and an adjacent transistor element, for example, gate or source/drain.

In some embodiments, the semiconductor device and method of fabrication disclosed below include one or more controllable buffer layers that are positioned below the source and drain. Areas in the buffer layers may be controllably opened to provide the contact access to the source and drain. The size and/or breadth of the openings may be selectively adjusted to control exposure to the BDI layer, which provides control over which elements above the BDI layer may be exposed to etching processes. The buffer layers protect the thin layer of BDI from the processes of forming the backside metallization for the contact. The material used for the buffer layers may be selected so that controlled removal of the material is accomplished to form a desired area for the backside contact. In some embodiments, insultation may be added to control the margin of error between the space in the buffer layers and the desired size of the backside contact. By using the insulation to fill in the space between the buffer and the metal, there is no need to use a self-alignment technique.

In some frontside methods, after the source and drain is formed, there is a recess down process that can cause pin holes in the source and drain material. During subsequent etching process, some of the chemistry can escape down the pin holes and attack the BDI layer compromising the integrity of an already thin layer.

As will be seen, features of the backside process disclosed below protect the BDI from backside process damage. The BDI layer is protected by the controllable buffer layers during any etching process during formation of the backside contact. The removal of buffer layer material is controllable when defining the area for the backside contact. So, the integrity of the BDI layer is not attacked by any of the chemistry or physical techniques used to remove material. In addition, it should be appreciated that the gate material above the BDI layer is also protected since the BDI layer does not have any compromised material that will subject the gate material to any chemistry during the formation of the backside contact.

For the sake of brevity, conventional techniques related to semiconductor device and integrated circuit fabrication may or may not be described in detail herein. Moreover, the various tasks and process steps described herein can be incorporated into a more comprehensive procedure or process having additional steps or functionality not described in detail herein. In particular, various steps in the manufacture of semiconductor devices and semiconductor-based integrated circuits are well known and so, in the interest of brevity, many conventional steps will only be mentioned briefly herein or will be omitted entirely without providing the well-known process details.

In the following detailed description, numerous specific details are set forth by way of examples in order to provide a thorough understanding of the relevant teachings. However, it should be apparent that the present teachings may be practiced without such details. In other instances, well-known methods, procedures, components, and/or circuitry have been described at a relatively high-level, without detail, in order to avoid unnecessarily obscuring aspects of the present teachings.

In one aspect, spatially related terminology such as “front,” “back, “frontside,” “backside,” “top,” “bottom,” “beneath,” “below,” “lower,” above,” “upper,” “side,” “left,” “right,” and the like, is used with reference to the direction of the Figures being described. Since components of embodiments of the disclosure can be positioned in a number of different directions, the directional terminology is used for purposes of illustration and is in no way limiting. Thus, it will be understood that the spatially relative terminology is intended to encompass different directions of the device in use or operation in addition to the direction depicted in the figures. For example, if the device in the figures is turned over, elements described as “below” or “beneath” other elements or features would then be oriented “above” the other elements or features. Thus, for example, the term “below” can encompass both an orientation that is above, as well as, below. Similarly, an element described as “on top of” of another element may mean either that the element is positioned above and is not necessarily in direct contact with the underlying element. The device may be otherwise oriented (rotated 90 degrees or viewed or referenced at other directions) and the spatially relative descriptors used herein should be interpreted accordingly.

As used herein, the terms “lateral”, “planar”, and “horizontal” describe an orientation parallel to a first surface of a chip or substrate. In the disclosure herein, the “first surface” may be the top layer of a semiconductor device where individual circuit devices are patterned in the semiconductor material.

As used herein, the term “vertical” describes an orientation that is arranged perpendicular to the first surface of a chip, chip carrier, chip substrate, or semiconductor body.

As used herein, the terms “coupled” and/or “electrically coupled” are not meant to mean that the elements must be directly coupled together—intervening elements may be provided between the “coupled” or “electrically coupled” elements. In contrast, if an element is referred to as being “directly connected” or “directly coupled” to another element, there are no intervening elements present. The term “electrically connected” refers to a low-ohmic electric connection between the elements electrically connected together. The phrase “electrically connected” does not necessarily mean that the elements must be directly in physical contact together—intervening elements may be provided between the “connected” or “electrically connected” elements.

Although the terms first, second, etc., may be used herein to describe various elements, these elements should not be limited by these terms. These terms are only used to distinguish one element from another. For example, a first element could be termed a second element, and, similarly, a second element could be termed a first element, without departing from the scope of example embodiments. Nor does describing an element as “first” or “second”, etc. necessarily mean that there is an order or priority to any of the elements. As used herein, the term “and/or” includes any and all combinations of one or more of the associated listed items.

Example embodiments are described herein with reference to cross-sectional illustrations that are schematic illustrations of idealized or simplified embodiments (and intermediate structures). As such, variations from the shapes of the illustrations as a result, for example, of manufacturing techniques and/or tolerances, may be expected. Thus, the regions illustrated in the figures are schematic in nature and their shapes do not necessarily illustrate the actual shape of a region of a device and do not limit the scope. It should be appreciated that the figures and/or drawings accompanying this disclosure are exemplary, non-limiting, and not necessarily drawn to scale.

It is to be understood that other embodiments may be used, and structural or logical changes may be made without departing from the spirit and scope defined by the claims. The description of the embodiments is not limiting. In particular, elements of the embodiments described hereinafter may be combined with elements of different embodiments.

### Definitions

Front End of Line (FEOL) Layer: The FEOL is a section of a semiconductor device that includes active and/or passive electrical components including for example, transistor.

Middle of Line (MOL) Layer: The middle of line layer MOL is a section of a semiconductor device that includes source and drain contacts and a gate contacts that are used to connect the source and drain, and the gate to back end of line interconnects.

Back End of Line (BEOL): The back end of line is a layer of integrated circuit fabrication where the individual electronic components become interconnected with wiring on a wafer or other substrate. In embodiments below, the BEOL may be shown placed on the “frontside” of a layer of electrical components.

Back Side Power Delivery Network (BSPDN): A back side power delivery network is a layer of connections connecting electrical components from the back side of their layer or support structure. In embodiments disclosed below, the BSPDN may be on a side of the MOL opposite the BEOL.

Substrate: Reference to a substrate may refer to material that provides a support structure to features in or on top of the substrate material. As used below, there may be more than one substrate present in an embodiment shown. Also, since embodiments below are generally shown in cross-section, it should be understood that a substrate for a layer with patterned features may not be visible in the view so as to highlight the features for the layer.

Buffer layer: A buffer layer refers to a layer of material providing physical protection for one material from another adjacent material. The buffer layer may be insulative or conductive depending on the desired buffering between adjacent material.

Sacrificial layer: A sacrificial layer may refer to a layer of material that includes one or more concentrations of material, that may be mixed, whose rate of removal during an etching or other removal process can be controlled based on the concentration of materials present. Generally, sacrificial layers are designated for whole or partial removal during the fabrication process, to be replaced by another material. In the embodiments disclosed below, sacrificial layers of varying concentrations may be used. An example of a sacrificial layer mix includes the use of silicon and germanium. Some example mixes may use concentrations of germanium in the 25% to 35% range for one layer. Another layer may include a mix with a concentration of germanium in the 50% to 60% range. While silicon germanium is described in the examples below, other mixes may be used for the purposes of controllably removing material in some areas or layers of the device.

### Example Device Structure

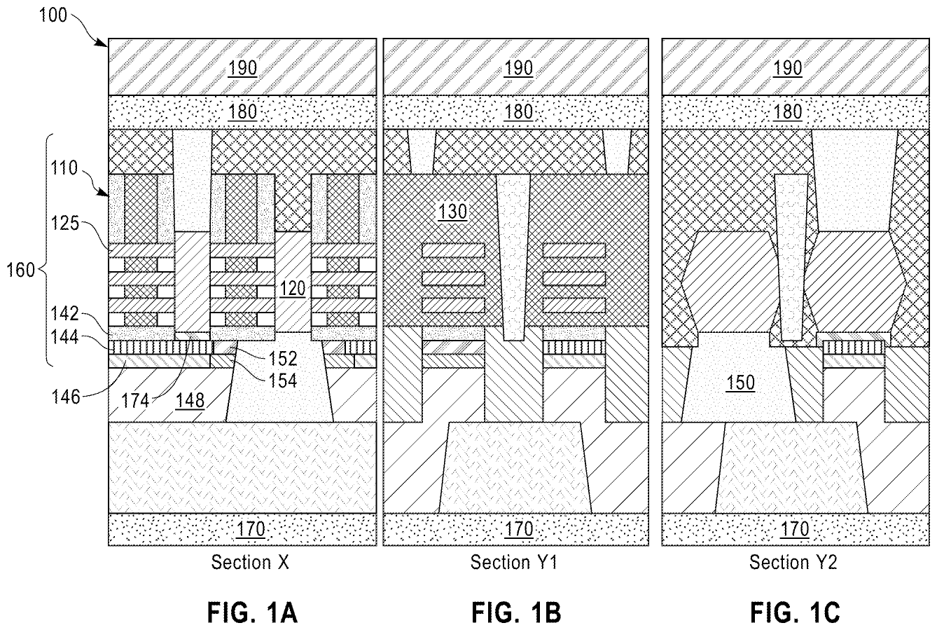

Referring now to FIGS. 1A-1C, a cross-sectional view of a semiconductor device 100 (referred to generally as the “device 100”) is shown, consistent with embodiments of the disclosure. As will be seen below, the embodiment shown in FIGS. 1A-1C is representative of a final result of a method of fabrication consistent with embodiments of the subject disclosure. To establish an orientation and points of reference, for purposes of the description below, the surface at the top of the semiconductor device 100 is considered the “frontside” and the surface at the bottom of the semiconductor device 100 is considered the “backside”. Thus, any action occurring from the top of the drawing and downward into the semiconductor device 100 should be considered as approaching the semiconductor device 100 from the “frontside”. Any action occurring from the bottom of the drawing and upward into the formation should be considered as approaching the formation from the “backside”.

In one embodiment, the semiconductor device 100 generally includes a FEOL and MOL layer 160, a BPSDN layer 170 on a backside of the FEOL and MOL layer 160. In some embodiments, a BEOL layer 180 may be on a frontside of the FEOL and MOL layer 160. In some embodiments, a carrier wafer 190 may be on a frontside of the BEOL layer 180.

In one embodiment, the FEOL and MOL layer 160 includes one or more transistor devices 110. The transistor device 110 includes a source and drain region 120 and a gate region 130. In some embodiments, the transistor device 110 is a nanosheet type device that includes a plurality of stacked semiconductor channels 125.

On the backside of the transistor device 110, a bottom dielectric isolation (BDI) layer 142 insulates the source and drain region 120 and the gate region 130 from underlying electrical elements. Embodiments generally include a contact 150, formed from the backside of the FEOL and MOL layer 160, providing electrical contact access to the transistor device 110 through the BDI layer 142. Accordingly, the contact 150 may be referred to below as the “backside contact 150” to distinguish from other contacts (such as frontside contacts) that may be present in different embodiments. Embodiments may include one or more buffer layers adjacent the backside contact 150 as will be seen in the description of an example fabrication below. In an embodiment, a pair of buffer layers 144 and 146 may be positioned between the BDI layer 142 and an underlying backside interlayer dielectric (BILD) 148. The backside contact 150 extends to pass through the buffer layers 144, 146, the BILD 148 and the aforementioned BDI layer 142. In some embodiments, another buffer layer 174 may be positioned between the buffer layer 144 and a source and drain region adjacent the source and drain region 120 connected to the backside contact 150. The buffer layers 144 and 146 may be formed from an “etch controllable” material. In an embodiment, the buffer layers 144 and 146 may be semiconductor alloys. The alloy composition of each buffer layer 144 and 146 may be specifically chosen so that they may be etched selective to surrounding structures. More specifically, the alloy composition of buffer layer 144 is chosen so that it may be etched selective to the BDI layer 142 and the buffer layer 146. The alloy composition of buffer layer 146 is chosen so that it may be etched selective to the buffer layer 144 and the BILD 148. In some embodiments, both the buffer layer 144 and the buffer layer 146 are made from a silicon germanium (SiGe); however, each may have different concentrations of germanium so that one can be etched or removed faster than the other. Doing so results in a tapered or staggered wall from the different respective sized openings at each buffer layer. The resultant opening will be used to define the area that will receive metallization for the backside contact 150. In some embodiments, the backside contact 150 may include a tapered sidewall indexed to the walls of a tapered opening (or a staggered sidewall to index with the wall of a staggered opening) so that the tapered opening accommodates the tapered walls of the backside contact 150. For example, buffer layer 144 may include a concentration of 30% germanium. Buffer layer 146 may include a concentration of 50% germanium. If subjected to a wet etch process for the same amount of time, the buffer layer 146 with its higher concentration of germanium will indent more than the buffer layer 144. In some embodiments, insulation layers 152 and 154 may be positioned in the areas indented by the controlled removal of buffer material. As will be appreciated, by using the buffer layers 144 and 146 along with insulation layers 152 and 154, control of the overlay margin for the backside contact 150 can be improved over what is conventionally performed in the field of backside fabrication. The diameter of the overlay may range from approximately 10nm to 15nm, which is larger than conventional overlay techniques that use self-alignment. It should be further appreciated that the backside contact 150 can be placed anywhere in the buffer layers 144 and 146, which avoids landing on the BDI layer 142 (or exposing the BDI layer 142 to etching processes from the backside during fabrication), thus protecting the already thin BDI layer 142 from potential damage from the backside.

In the description of the method for fabrication below, one or more substrates may be present at any one stage. Substrates can be the same material or different materials. Substrates can be made of any suitable substrate material, such as, for example, monocrystalline Si, silicon germanium (SiGe), III-V compound semiconductor, II-VI compound semiconductor, or semiconductor-on-insulator (SOI). Group III-V compound semiconductors, for example, include materials having at least one group III element and at least one group V element, such as one or more of aluminum gallium arsenide (AlGaAs), aluminum gallium nitride (AlGaN), aluminum arsenide (AlAs), aluminum indium arsenide (AlIAs), aluminum nitride (AlN), gallium antimonide (GaSb), gallium aluminum antimonide (GaAlSb), gallium arsenide (GaAs), gallium arsenide antimonide (GaAsSb), gallium nitride (GaN), indium antimonide (InSb), indium arsenide (InAs), indium gallium arsenide (InGaAs), indium gallium arsenide phosphide (InGaAsP), indium gallium nitride (InGaN), indium nitride (InN), indium phosphide (InP) and alloy combinations including at least one of the foregoing materials. The alloy combinations can include binary (two elements, e.g., gallium (III) arsenide (GaAs)), ternary (three elements, e.g., InGaAs) and quaternary (four elements, e.g., aluminum gallium indium phosphide (AlInGaP)) alloys.

### Example Methodology of Manufacture

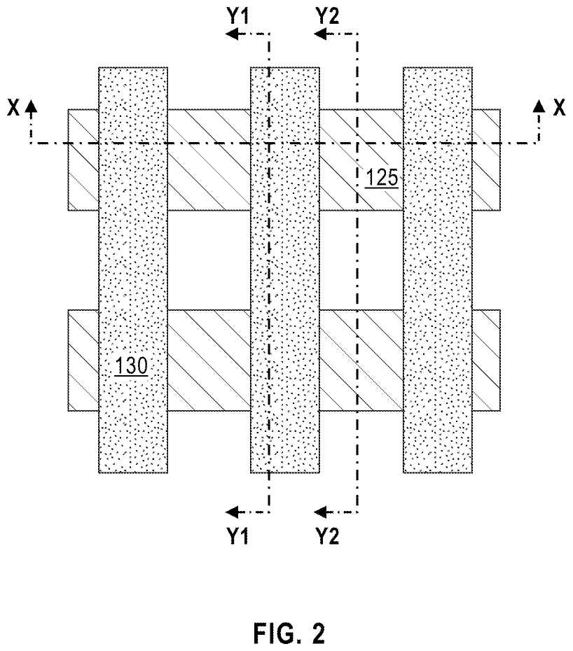

In the following, a process describes a general method of forming a semiconductor device that protects a BDI layer and transistor elements above the BDI layer during backside formation of a contact is shown according to an embodiment. FIG. 2 shows a legend providing the various views of the semiconductor device during the fabrication process. In general, the legend shows a top view of the device. The “A” series of figures show/depict/illustrate a cross-sectional view of the semiconductor device 100 taken along line X-X. Similarly, the “B” series of figures show/depict/illustrate a cross-sectional view of the semiconductor device 100 taken along line Y1-Y1. The “C” series of figures show/depict/illustrate a cross-sectional view of the semiconductor device 100 taken along line Y2-Y2. Line X-X is a cross-section view perpendicular to the gate in a fin region. Line Y1-Y1 shows a cross-sectional view through the gate. Line Y2-Y2 shows a cross-sectional view of the source and drain. The legend in FIG. 2 may be referenced for each subsequent series of figures (3A-3C to 9A-9C) during the description of the formation.

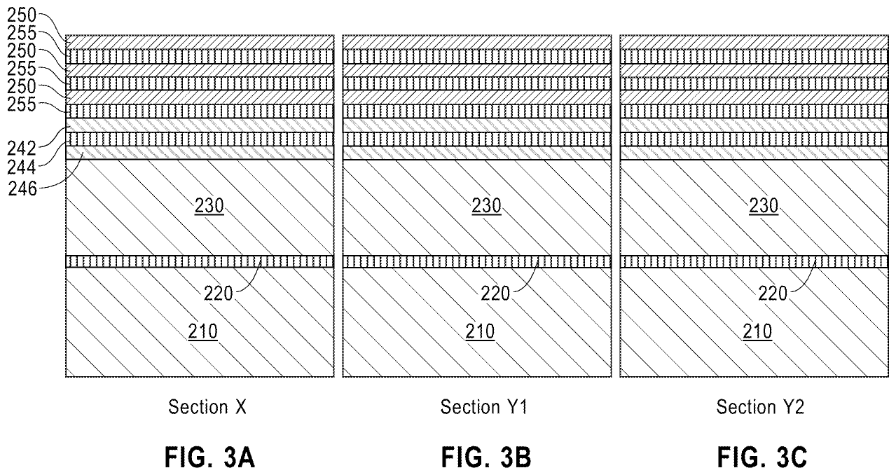

FIGS. 3A-3C show a semiconductor structure 200 during an intermediate step of a method of fabricating a transistor with a non-self aligned backside contact according to an exemplary embodiment. The structure 200 includes a first substrate layer 210, an etch stop layer 220 on top of the first substrate layer 210, a second substrate layer 230 on top of the etch stop layer 220, a first buffer layer 246 on top of the second substrate layer 230, a second buffer layer 244 on top of the first buffer layer 246, a placeholder layer 242 on top of the second buffer layer 244, and then a stack of nanosheets that include alternating of layers of semiconductor material 250 and sacrificial layers 255 on top of the placeholder layer 242. The sacrificial layers 255, the placeholder layer 242, and the buffer layers 244 and 246 may be, for example, layers of silicon germanium that may include different concentrations of germanium at different levels in the formation. The etch stop layer 220 may also be silicon geranium or other suitable etch stop material (for example, a buried oxide layer (BOX)).

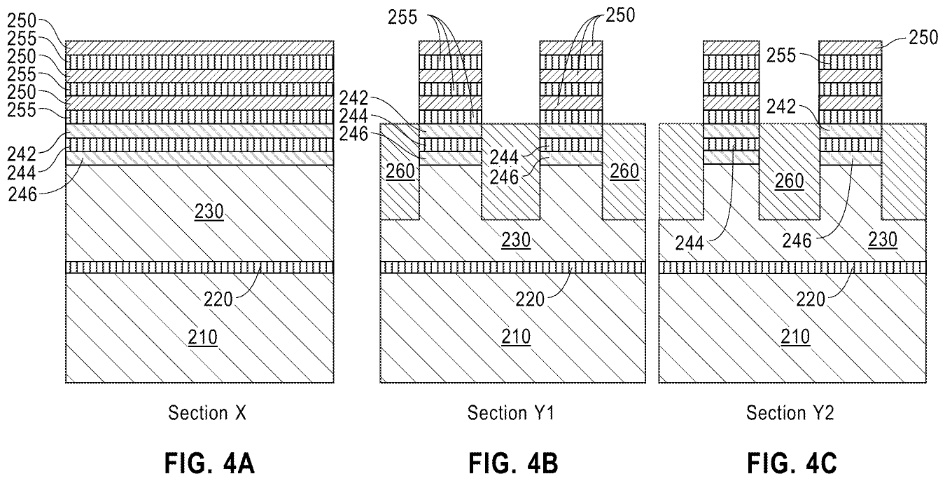

FIGS. 4A-4C, 5A-5C, and 6A-6C show the structure 200 after patterning the nanosheets into stacks and forming shallow trench isolation (STI) features according to an embodiment. The process may form two nanosheet stacks as shown in FIGS. 4B and 4C. The pattern may recess material down into the second substrate layer 230. The STI layer 260 may be formed in the gaps in front of, in between, and behind the fin structures. In some embodiments, the STI level lands approximately in the middle of the level of the placeholder layer 242.

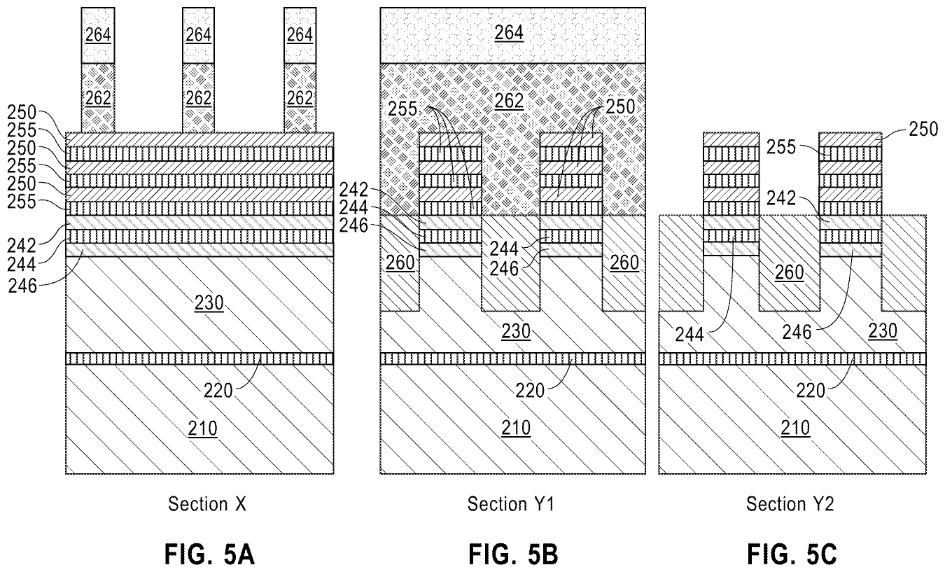

FIGS. 5A-5C show the formation after forming a dummy gate region 262. The dummy gate region 262 material may be deposited on top of the top semiconductor layer 250. A mask 264 may be applied on top of the dummy gate region 262 material for removing extraneous dummy gate material to define areas forming an eventual gate region (shown further below). The dummy gate region 262 and the mask 264 are noticeably absent from FIG. 5C since the perspective is along the source and drain region.

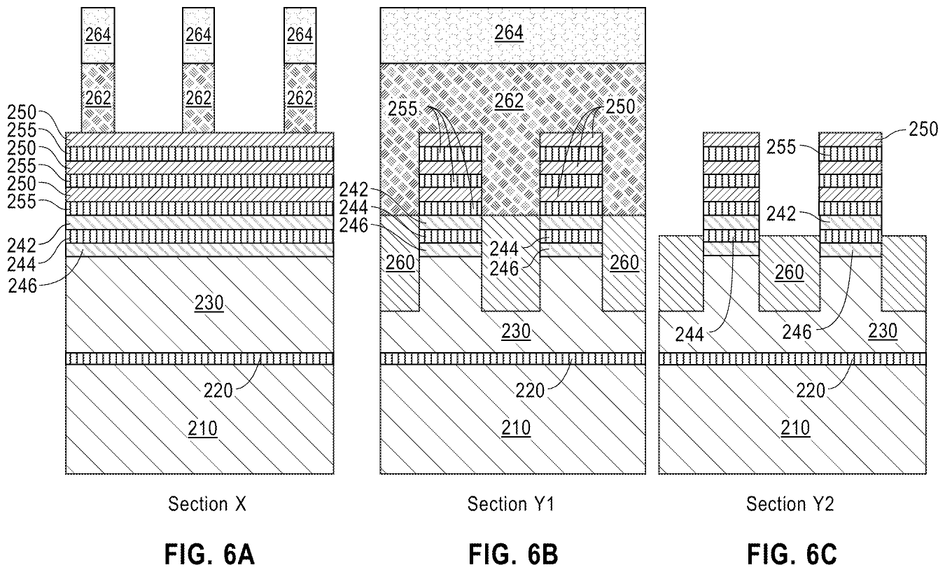

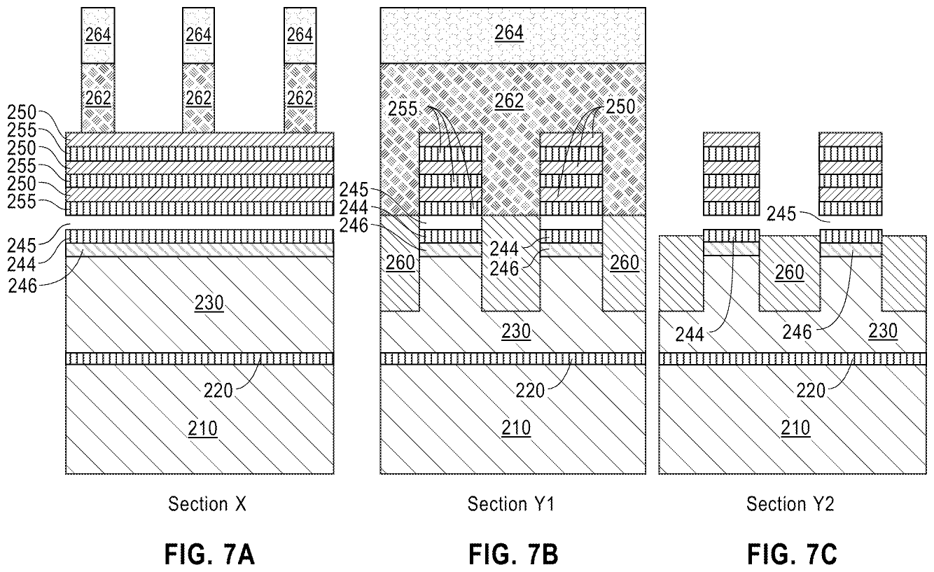

FIGS. 6A-6C show a formation after applying an oxide etch process to reduce a height of the STI layer 260 in the source and drain region (see FIG. 6C in particular). As can be seen comparing FIG. 6C to FIG. 5C, the height of the STI layer 260 was etched down from the level of placeholder layer 242 to the level of buffer layer 244. FIGS. 7A-7C show a formation after applying a selective etch (or selective removal) process of the placeholder layer 242. The removal process may include a wet etch process that focuses on removing material with the amount of germanium present in the placeholder layer 242. The reduction of the STI height in FIG. 5C completely exposes the placeholder layer 242, making the process for selective removal of the entire layer much easier. Any other layers that have a similar germanium concentration (for example, buffer layer 246) are below the buffer layer 244 (which has a different germanium concentration) and are protected by the STI layer 260 during the wet etch. The removal of placeholder material leaves behind a cavity 245.

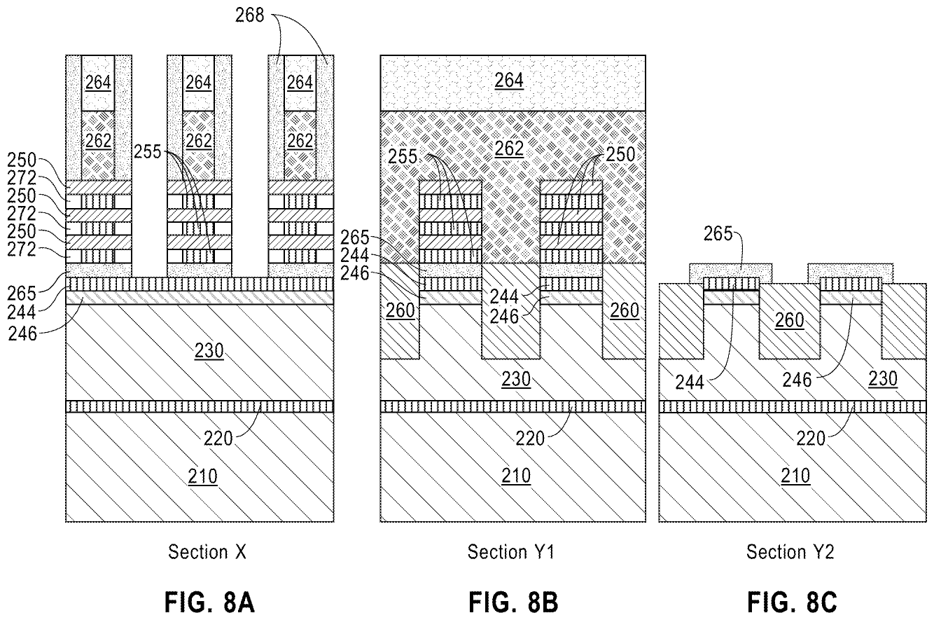

FIGS. 8A-8C show a formation after forming a BDI layer 265 in the cavity 245 (of FIGS. 7A-7C). The cavity 245 may be filled with dielectric material to form the BDI layer 265. Some embodiments may include a layer of gate spacer material 268 (which may use the same material as the BDI layer 265) applied to the sides of the pillar structures. After the BDI layer 265 and gate spacer material 268 formation, the stacks of nanosheets and the BDI layer 265 are etched out below the sides of the fins of the dummy gate features, down to the top of the second buffer layer 244. After the nanosheet stacks are etched out, an indentation process may be applied to the sacrificial layers 255 (see FIG. 8A) left on the fins. The voids left behind from indentation may receive inner spacer material 272.

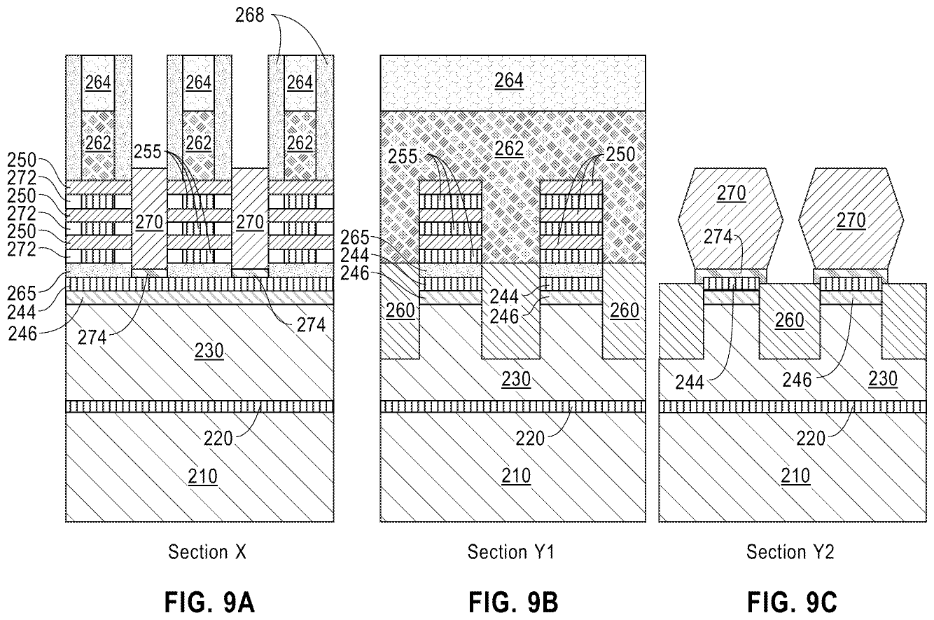

FIGS. 9A-9C shows a formation after forming source and drain regions 270. From the formation shown in FIGS. 8A-8C, areas of the BDI layer 265 that are exposed may be opened up, (removed). A third buffer layer 274 (for example silicon or another semiconductor material) may be deposited in the areas opened up in the BDI layer 265, over the second buffer layer 244. After the third buffer layer 274 is deposited, an epitaxial growth may be used to form the source and drain on top of the third buffer layer 274.

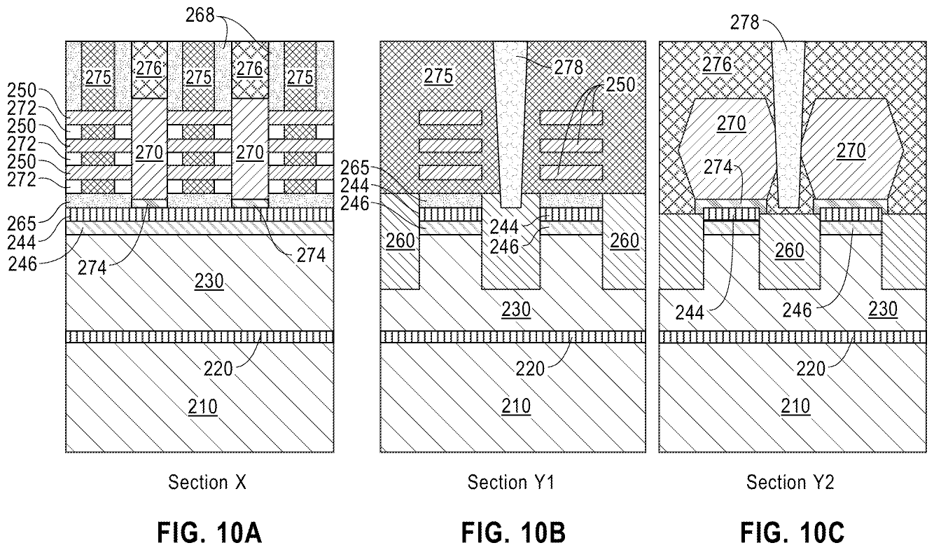

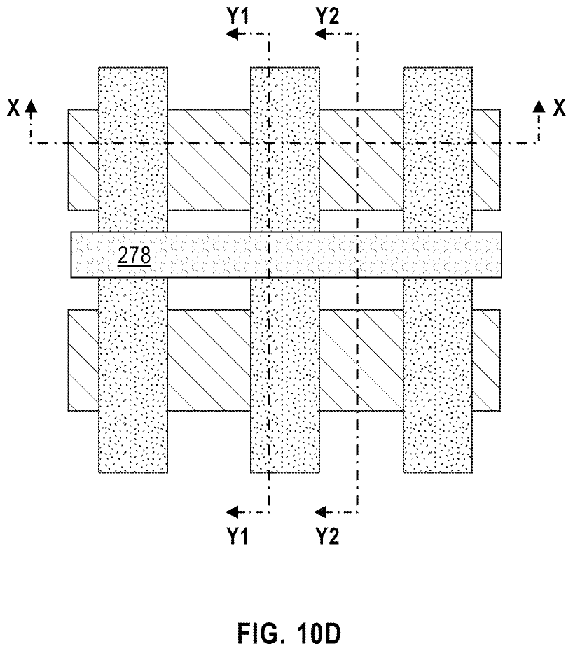

FIGS. 10A-10C show a formation after forming the gate regions 275. In forming the gate regions 275, an interlayer dielectric 276 may be deposited in open areas that can be seen in FIGS. 9A-9C. Referring temporarily back with concurrent reference to FIGS. 6A-6C, the dummy gate region 262 material and hard mask 264 sections are pulled (removed). The sacrificial layers 255 are also removed (using for example, selective etching as described above). Gate material (using for example, a high-K gate metal) may be used to replace the areas vacated by the dummy gate region 262 material and the sacrificial layers 255, forming the gate region 275. In some embodiments, a section of the gate region 275 may be subjected to a gate cut region 278. In some embodiments, a planarization process may be applied to the frontside of the formation. The legend in FIG. 10D is similar to the legend in FIG. 2, except that the legend is updated to show the addition of the gate cut region 278.

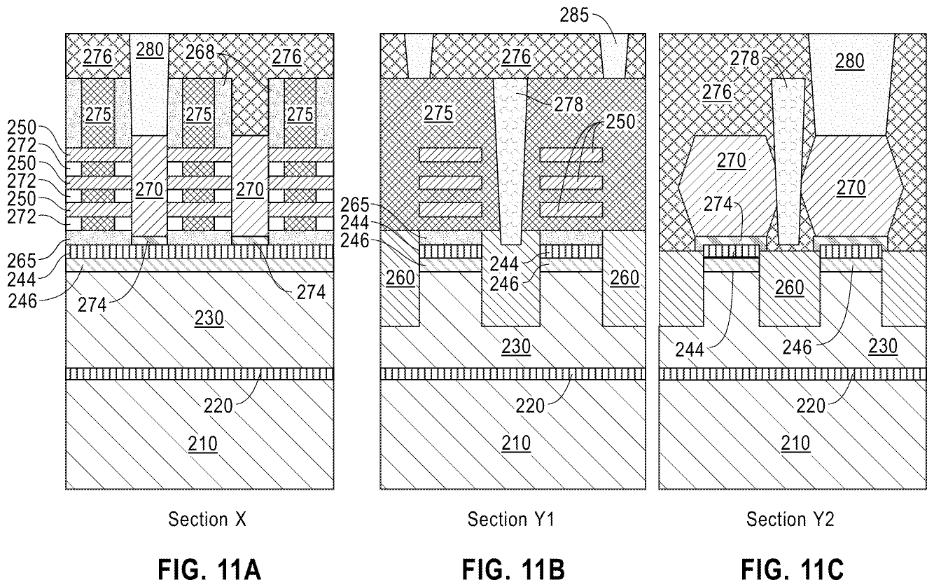

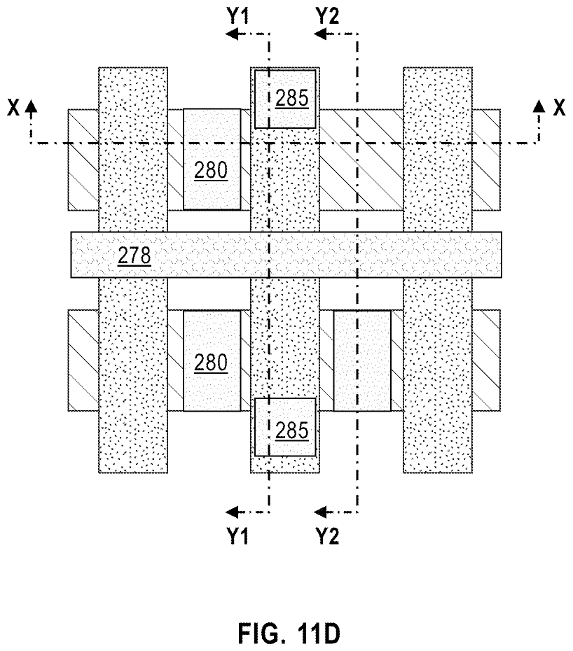

FIGS. 11A-11C show a formation after forming metal contacts 280 and 285. Additional interlayer dielectric 276 may be backfilled on the frontside of the device. Some of the interlayer dielectric 276 may be patterned above one of the source and drain regions 270 and backfilled with metal to form source and drain contact 280. (See FIGS. 11A and 11C). Some of the interlayer dielectric 276 may be patterned above the gate region 275 and backfilled with metal to form gate contact 285. FIG. 11D is similar to the legend in FIG. 10D, except that the legend is updated to show the addition of the contacts 280 and 285. In the following figures, the legend in 11D may be referenced throughout because the following changes to the device primarily occur on the backside and the view from the topside does not change.

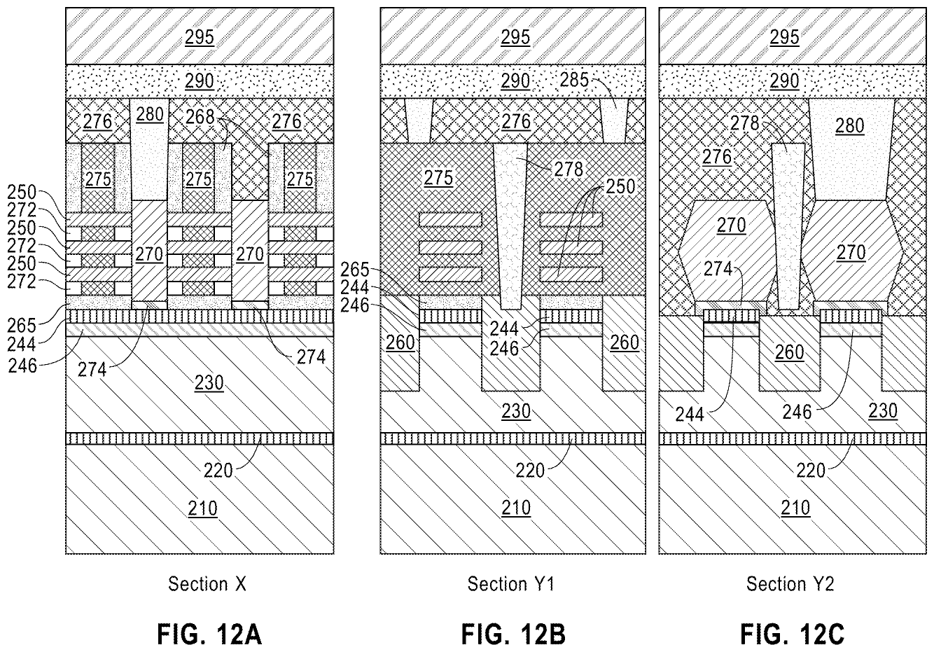

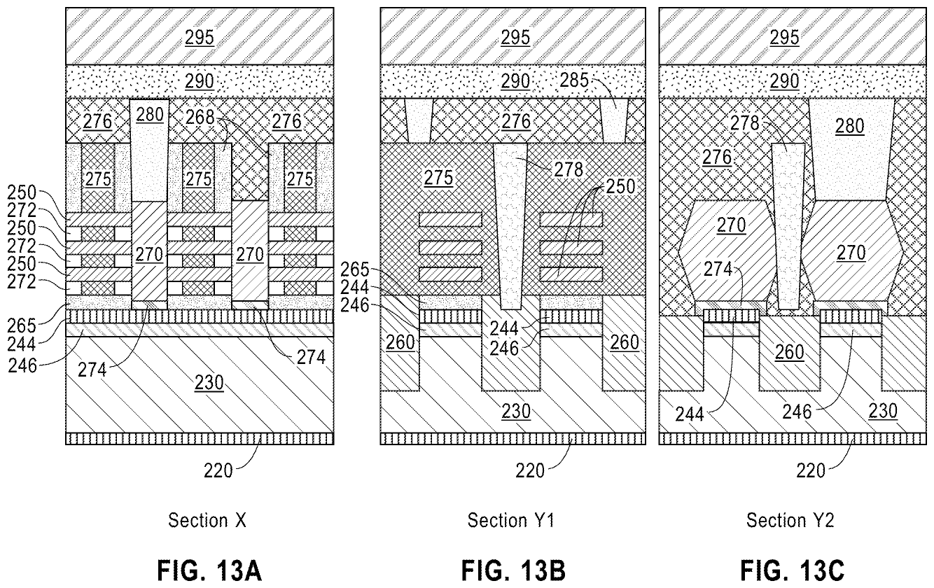

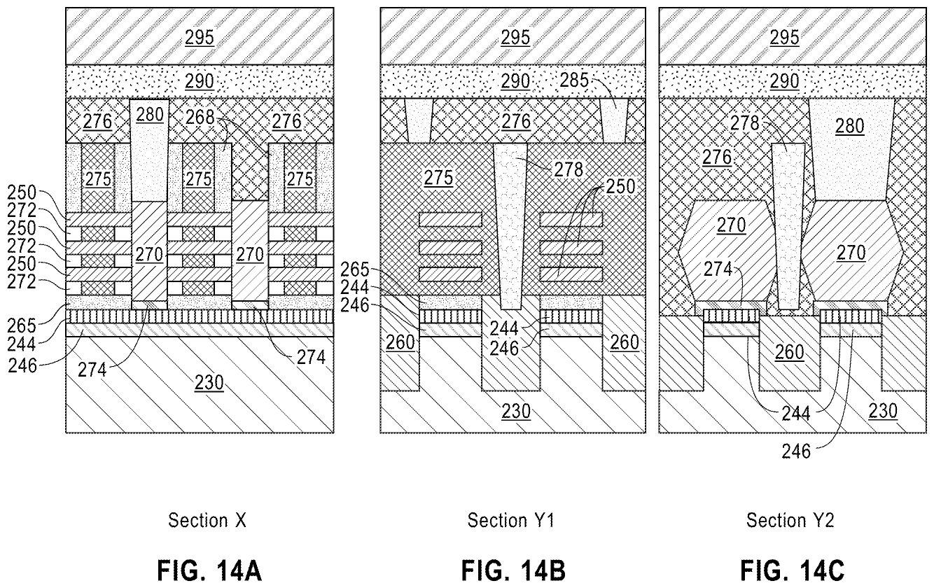

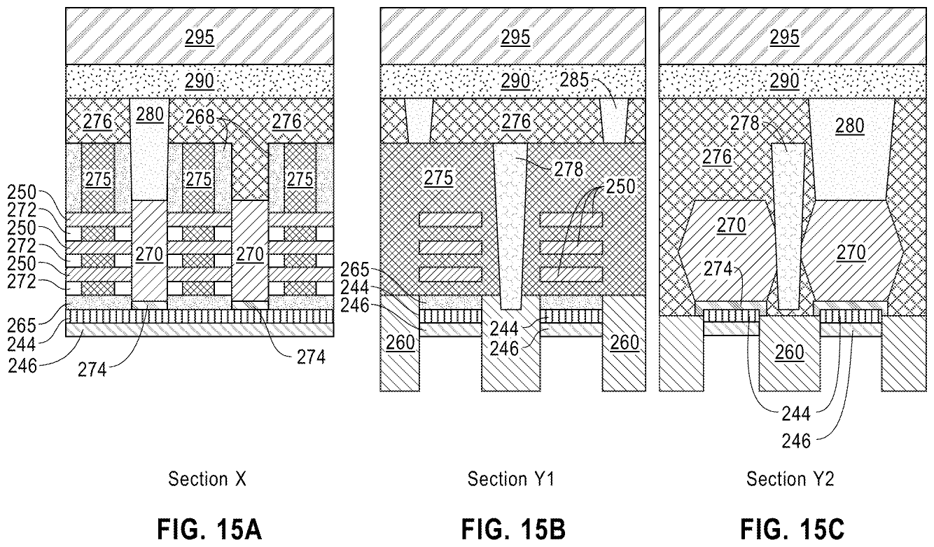

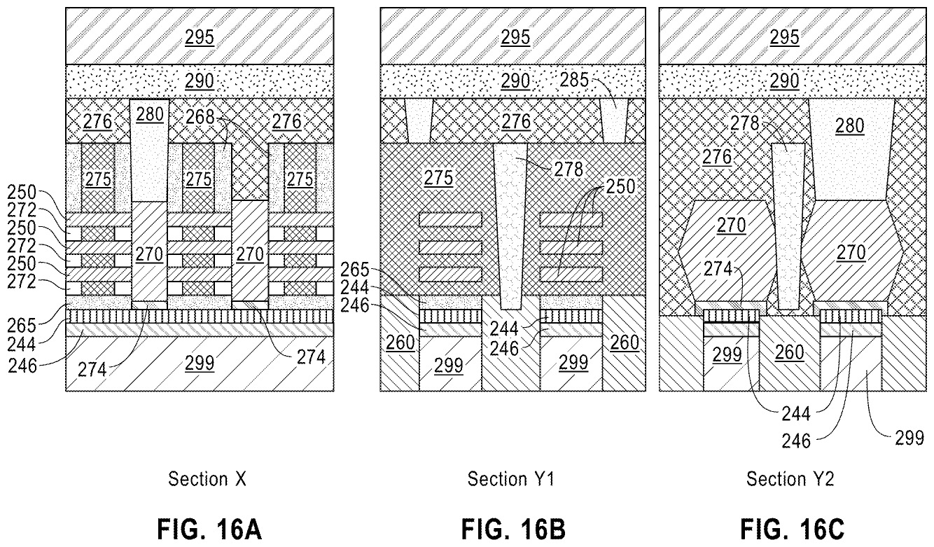

FIGS. 12A-12C show a formation after the addition of a BEOL 290 on the top surface of the MOL. Some embodiments may form a carrier wafer 295 on top of the BEOL 290. FIGS. 13A-13C show formation of the device after a wafer flip and removal of the substrate layer 210 (shown in the previous formation in FIGS. 12A-12C), exposing the etch stop layer 220. The removal of substrate layer 210 may be performed by silicon grinding, CMP, and/or wet etching as is known in the art of semiconductor material removal. It will be understood that the orientation is kept consistent with the formation shown in FIGS. 12A-12C for sake of illustration, even though the process is occurring on the back side of the device. FIGS. 14A-14C show a formation after removal of the etch stop layer 220 and exposing the substrate layer 230 from the backside. FIGS. 15A-15C show a formation after removing the substrate layer 230, including in areas around the STI layer 260, exposing areas of the first buffer layer 246. In FIGS. 16A-16C, the process may deposit a backside interlayer dielectric 299 over the first buffer layer 246 and around the STI layer 260.

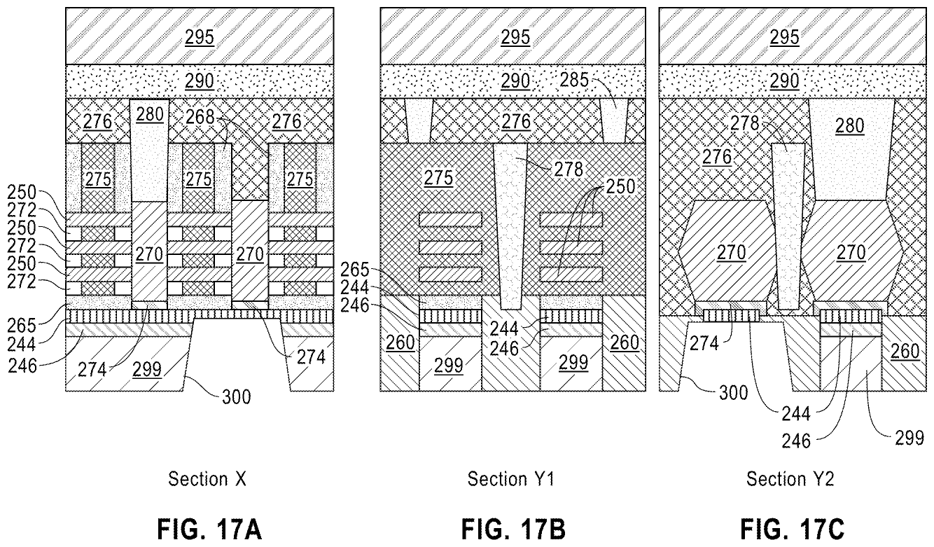

FIGS. 17A-17C show a formation after preparing the backside of the device for a backside contact formation. The backside may be patterned to open up an area of the backside interlayer dielectric 299 through the first buffer layer 246 under one of the source and drain regions. The opened-up area defined by walls 300 define some of the eventual backside contact area. The patterning may also open up some of the second buffer layer 244 so that the walls 300 land partially within the second buffer layer 244 (see for example FIG. 17A). To control the removal of the buffer layer 244 and 246, a timed or reactive ion etch may be used so that the material removed does not exceed the margin desired (in other words, does not go past the second buffer layer 244 into the BDI layer 265 (see FIGS. 9A-9C)). In some embodiments, the germanium concentration in the first buffer layer 246 may be higher than the concentration of germanium in the second buffer layer 244. Thus, when the etch process is applied, the material in the second buffer layer 244 reacts less aggressively to the etch process than the material in the first buffer layer 246 during this stage of the process providing some initial protection from over etching into the BDI layer 265. In some embodiments, the thickness of buffer layers 244 and 246 combined may be approximately 14 nm to 20 nm. With enough material present, the process for removing buffer material can be calculated or controlled to avoid punching through to the BDI layer 265.

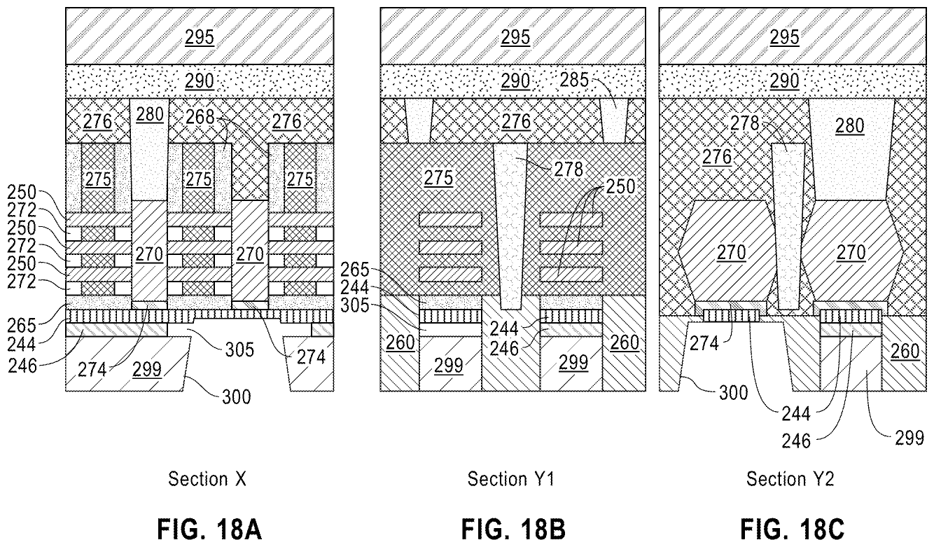

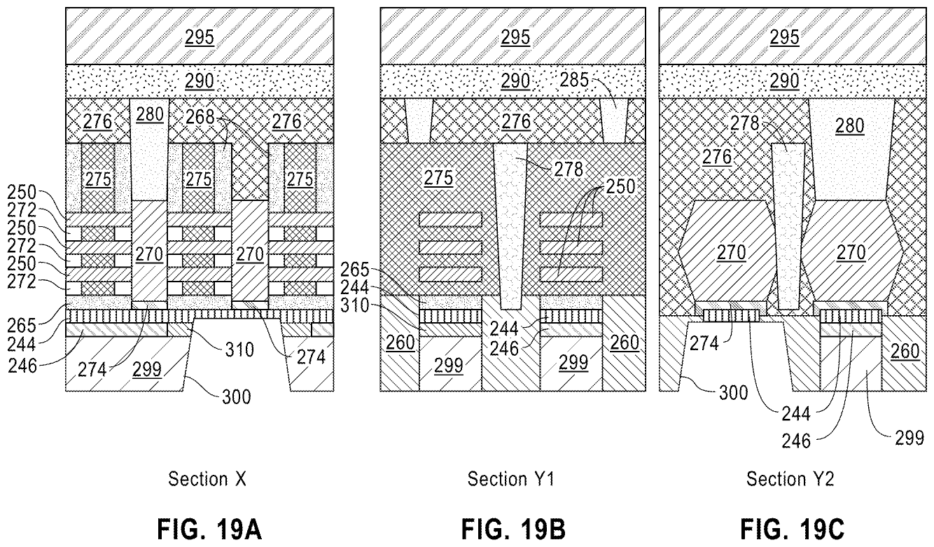

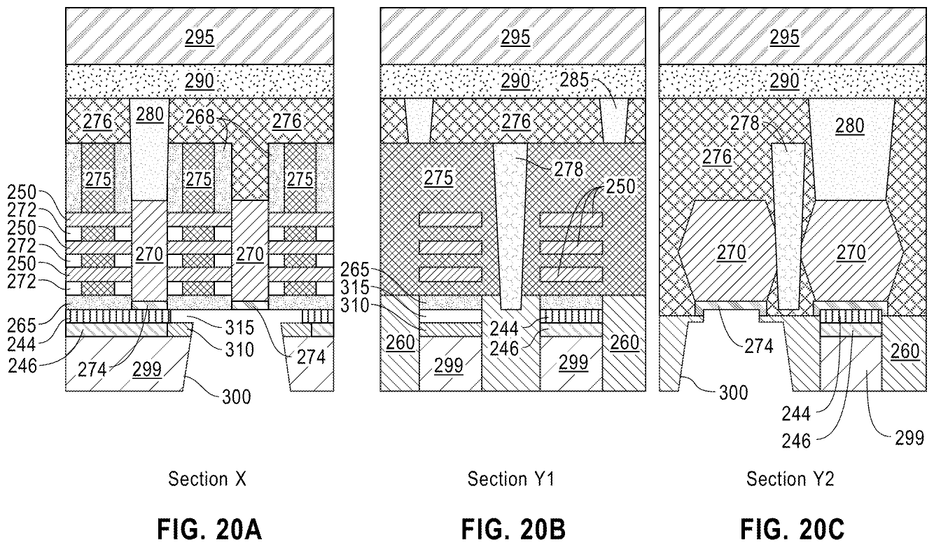

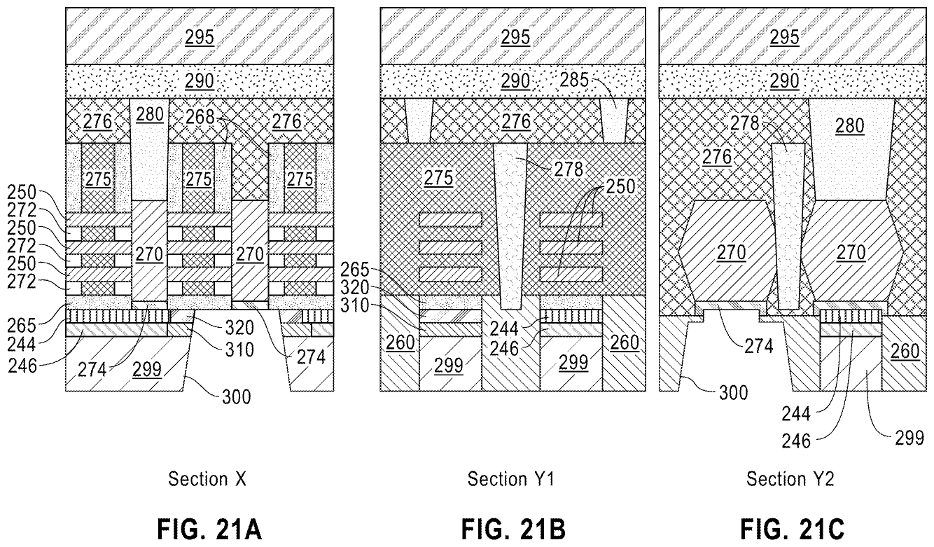

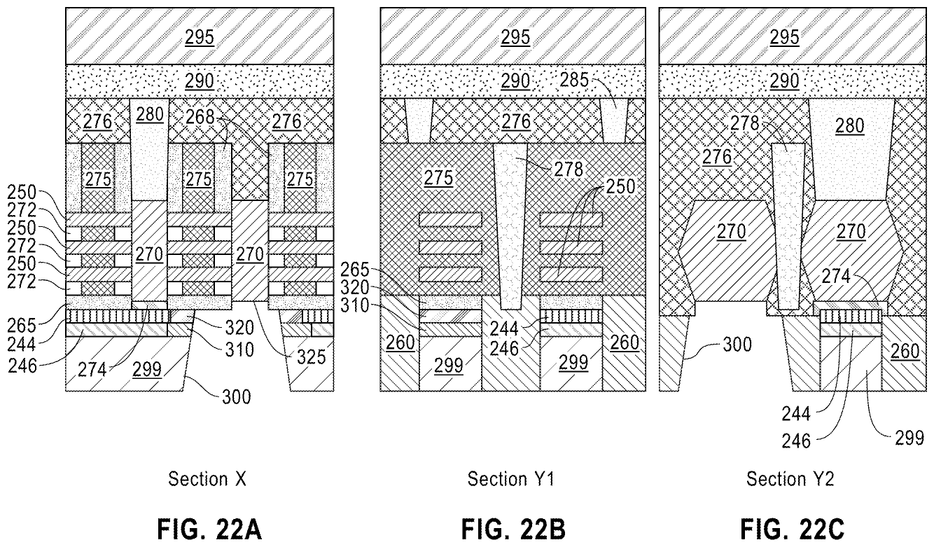

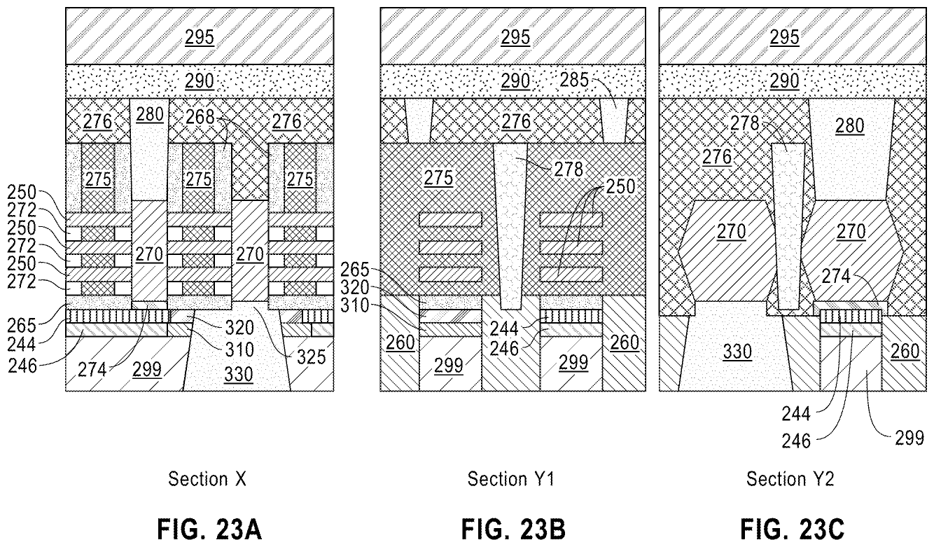

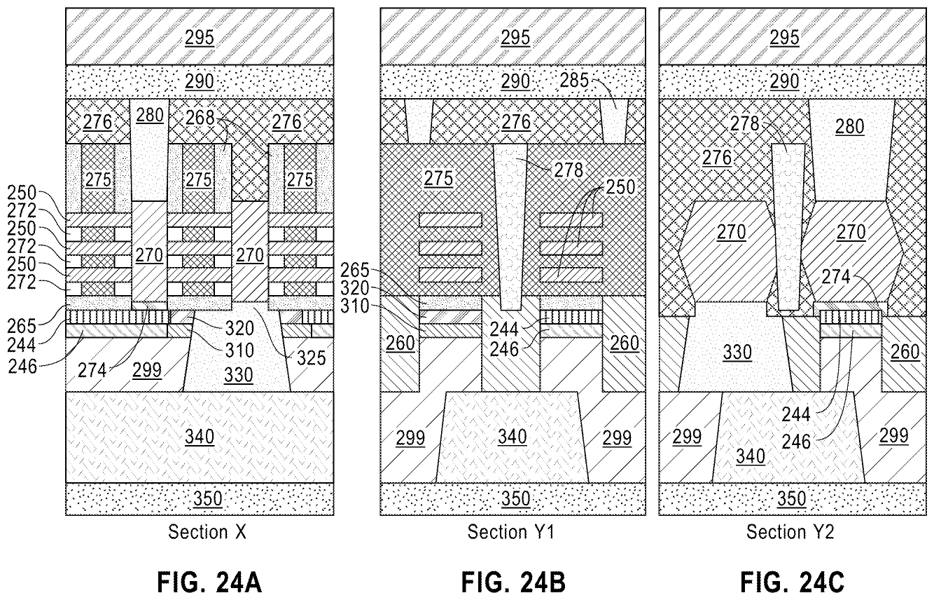

FIGS. 18A-18C show the formation after indenting or selectively removing some of the first buffer layer 246 next to the wall 300 with respect to second buffer layer 244 by, for example, a wet etch process. The areas 305 of removed first buffer layer 246 may be backfilled with a dielectric inner spacer material 310 as shown in FIGS. 19A-19C. In some embodiments, the dielectric inner spacer material 310 shares the same level as the first buffer layer 246. FIGS. 20A-20C show indentation or selective removal of some of the second buffer layer 244 next to the wall 300 with respect to the third buffer layer 274 and BDI layer 265 by, for example, a wet etch process. Removal of the second buffer layer 244 exposes the third buffer layer 274 and BDI layer 265. As may be appreciated, the selective removal of the second buffer layer 244 with respect to BDI layer 265 allows minimum damage to BDI layer 265 that otherwise may happen by, for example, a dry etch process. The open area 315 left behind from removal of the second buffer layer 244 may be backfilled with dielectric inner spacer material 320 as shown in FIGS. 21A-21C. In FIGS. 22A-22B, the third buffer layer 274 may be removed exposing the backside 325 of the source and drain region 270. In some embodiments, a portion of the third buffer layer 274 remains positioned between the second buffer layer 244 and a backside of the adjacent unnumbered source and drain region. FIGS. 23A-23C show the formation after metal is deposited into the cavity defined by overlay wall 300 and the area where third buffer layer 274 was removed, forming backside contact 330. The backside contact 330 provides electrical contact from the backside to the source and drain region 270 as seen in FIGS. 23A and 23C. The bottom dielectric isolation layer 265 is in position to isolate the backside contact 330 from the gate region 275. The bottom dielectric isolation layer 265 may also be in position to isolate the backside contact 330 from the adjacent unnumbered source and drain region and/or adjacent gate region in the transistor. As may be appreciated, the dielectric inner spacer material 310 and 320 also allow the process to control the overlay diameter of the contact area (which can be as large as 10 to 15 nm) to avoid overextending the contact area inadvertently under an adjacent source and drain region. FIGS. 24A-24C show the formation after a backside power rail 340 is formed over the backside contact 330. In some embodiments, a backside power delivery network 350 may be formed behind the back side of the backside power rail 340 and backside interlayer dielectric 299. The embodiment shown in FIGS. 24A-24C is similar to the embodiment described in FIGS. 1A-1C.

### Conclusion

The descriptions of the various embodiments of the present teachings have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

While the foregoing has described what are considered to be the best state and/or other examples, it is understood that various modifications may be made therein and that the subject matter disclosed herein may be implemented in various forms and examples, and that the teachings may be applied in numerous applications, only some of which have been described herein. It is intended by the following claims to claim any and all applications, modifications and variations that fall within the true scope of the present teachings.

The components, steps, features, objects, benefits and advantages that have been discussed herein are merely illustrative. None of them, nor the discussions relating to them, are intended to limit the scope of protection. While various advantages have been discussed herein, it will be understood that not all embodiments necessarily include all advantages. Unless otherwise stated, all measurements, values, ratings, positions, magnitudes, sizes, and other specifications that are set forth in this specification, including in the claims that follow, are approximate, not exact. They are intended to have a reasonable range that is consistent with the functions to which they relate and with what is customary in the art to which they pertain.

Numerous other embodiments are also contemplated. These include embodiments that have fewer, additional, and/or different components, steps, features, objects, benefits, and advantages. These also include embodiments in which the components and/or steps are arranged and/or ordered differently.

While the foregoing has been described in conjunction with exemplary embodiments, it is understood that the term “exemplary” is merely meant as an example, rather than the best or optimal. Except as stated immediately above, nothing that has been stated or illustrated is intended or should be interpreted to cause a dedication of any component, step, feature, object, benefit, advantage, or equivalent to the public, regardless of whether it is or is not recited in the claims.

It will be understood that the terms and expressions used herein have the ordinary meaning as is accorded to such terms and expressions with respect to their corresponding respective areas of inquiry and study except where specific meanings have otherwise been set forth herein. Relational terms such as first and second and the like may be used solely to distinguish one entity or action from another without necessarily requiring or implying any actual such relationship or order between such entities or actions. The terms “comprises,” “comprising,” or any other variation thereof, are intended to cover a non-exclusive inclusion, such that a process, method, article, or apparatus that comprises a list of elements does not include only those elements but may include other elements not expressly listed or inherent to such process, method, article, or apparatus. An element proceeded by “a” or “an” does not, without further constraints, preclude the existence of additional identical elements in the process, method, article, or apparatus that comprises the element.

The Abstract of the Disclosure is provided to allow the reader to quickly ascertain the nature of the technical disclosure. It is submitted with the understanding that it will not be used to interpret or limit the scope or meaning of the claims. In addition, in the foregoing Detailed Description, it can be seen that various features are grouped together in various embodiments for the purpose of streamlining the disclosure. This method of disclosure is not to be interpreted as reflecting an intention that the claimed embodiments have more features than are expressly recited in each claim. Rather, as the following claims reflect, inventive subject matter lies in less than all features of a single disclosed embodiment. Thus, the following claims are hereby incorporated into the Detailed Description, with each claim standing on its own as a separately claimed subject matter.

What is claimed is:

1. A semiconductor device, comprising:
a transistor device, including:
a source and drain region; and
a gate region;
a bottom dielectric isolation layer on a backside of the transistor device;
a buffer layer on a backside of the bottom dielectric isolation layer;
a first conductive contact positioned on the backside of the transistor device in contact with a backside of the source and drain region, through the bottom dielectric isolation layer and through the buffer layer; and
a second conductive contact in contact with the gate region from a frontside of the gate region.

2. The semiconductor device of claim 1, further comprising an insulation layer positioned between the first conductive contact and the buffer layer.

3. The semiconductor device of claim 2, wherein a dielectric inner spacer layer is positioned on a same level as the buffer layer.

4. The semiconductor device of claim 1, wherein the bottom dielectric isolation layer is in position to isolate the first conductive contact from the gate region.

5. The semiconductor device of claim 1, wherein the bottom dielectric isolation layer is in position to isolate the first conductive contact from an adjacent source and drain region.

6. The semiconductor device of claim 5, further comprising a buffer layer positioned between the buffer layer and a backside of the adjacent source and drain region.

7. The semiconductor device of claim 1, wherein the transistor device includes a stack of nanosheets.

8. A semiconductor device, comprising:
a transistor device in a front end of line layer, including:
a source and drain region; and
a gate region;
a bottom dielectric isolation layer in the front end of line layer and on a backside of the transistor device;
a first sacrificial layer on a backside of the bottom dielectric isolation layer including a first controlled opening;
a middle of line layer;
a back end of line layer coupled to a frontside of the middle of line layer;
a first conductive contact positioned on a backside of the transistor device in contact with a backside of the source and drain region, through the bottom dielectric isolation layer and through the first controlled opening of the first sacrificial layer;
a second conductive contact in contact with the gate region from a frontside of the gate region and in contact with the back end of line layer;
a backside power delivery network coupled to a back side of the front end of line layer; and
a power rail in the backside power delivery network in contact with a backside of the first conductive contact.

9. The semiconductor device of claim 8, further comprising a second sacrificial layer positioned between the first sacrificial layer and the bottom dielectric isolation layer, wherein the first conductive contact is in contact with the backside of the source and drain region through a second controlled opening in the second sacrificial layer.

10. The semiconductor device of claim 9, wherein:
the first controlled opening in the first controlled opening is larger than the second controlled opening; and
the first conductive contact includes a tapered sidewall indexed through the first and second controlled openings.

11. The semiconductor device of claim 8, further comprising a first dielectric inner spacer layer positioned in the first controlled opening between the first conductive contact and the first sacrificial layer.

12. The semiconductor device of claim 11, further comprising a second dielectric inner spacer positioned in a second controlled opening between the first conductive contact and a second sacrificial layer.

13. The semiconductor device of claim 12, wherein a first dielectric inner spacer and the second dielectric inner spacer are in position to isolate the first conductive contact from an adjacent source and drain region.

14. The semiconductor device of claim 8, wherein the bottom dielectric isolation layer is in position to isolate the first conductive contact from the gate region.

15. A method of manufacturing a semiconductor device, comprising:
forming a transistor device including a source and drain region and a gate region;
forming a bottom dielectric isolation layer on a backside of the transistor device;
forming a first opening in the bottom dielectric isolation layer under a backside of the source and drain region;
forming at least one sacrificial layer on a backside of the bottom dielectric isolation layer;
selectively removing a material from the sacrificial layer;
controlling a formation of a second opening in the sacrificial layer during the selective removal of material, wherein the second opening is positioned at least partly under the first opening; and
forming a conductive contact from the backside of the sacrificial layer, in the first opening and in the second opening, in contact with the backside of the source and drain region, through the bottom dielectric isolation layer.

16. The method of claim 15, further comprising forming an insulation layer in the second opening in between the material of the sacrificial layer and the conductive contact.

17. The method of claim 15, wherein the formation of the bottom dielectric isolation layer is in position to isolate the conductive contact from the gate region.

18. The method of claim 16, wherein forming the bottom dielectric isolation layer comprises positioning the insulation layer to isolate the conductive contact from an adjacent source and drain region.

19. The method of claim 15, further comprising:
forming a buffer layer in the first opening, under the backside of the source and drain region; and
removing the buffer layer after the formation of the second opening and prior to forming the conductive contact.

20. The method of claim 15, further comprising forming the at least one sacrificial layer using a plurality of sacrificial layers, wherein openings of respective sacrificial layers are controlled to define different sized openings to accommodate a tapered wall of the conductive contact.
